(19) United States
(12) Patent Application Publication
(10) Pub. No.: US 2024/0068804 A1
(43) Pub. Date: Feb. 29, 2024

(54) MULTI-PITCH GRID OVERLAY TARGET FOR SCANNING OVERLAY METROLOGY

(71) Applicant: KLA Corporation, Milpitas, CA (US)

(72) Inventors: Yuval Lubashevsky, Haifa (IL); Itay Gdor, Tel-Aviv (IL); Daria Negri, Nesher (IL); Eitan Hajaj, Ashqelon (IL)

(21) Appl. No.: 18/234,773

(22) Filed: Aug. 16, 2023

Related U.S. Application Data
(60) Provisional application No. 63/400,131, filed on Aug. 23, 2022.

(51) Int. Cl. G01B 11/27; G01B 9/02

(52) U.S. Cl. CPC G01B 11/272; G01B 9/02043; H01L 21/682

(57) ABSTRACT

An overlay metrology system with pitches in multiple directions in a single cell is disclosed. The overlay target may, according to a metrology recipe, include a multi-layer structure on two or more layers of a cell of the sample. The multi-layer structure may include structures in each layer having one or more pitches in one or more directions of periodicity. The multi-layer structure may include structures with a first pitch in a first direction, a second pitch in a second direction, a third pitch in the first direction, and a fourth pitch in the second direction. At least one of the first pitch or the third pitch may be different than at least one of the second pitch or the fourth pitch.

### CROSS-REFERENCE TO RELATED APPLICATION

The present application claims the benefit under 35 U.S.C. § 119(e) of U.S. Provisional Application Ser. No. 63/400,131, filed Aug. 23, 2022, entitled “New OVL Metrology Target Design for Two-Dimensional Scanning Measurement”, naming Yuval Lubashevsky, Itay Gdor, Daria Negri, and Eitan Hajaj as inventors, which is incorporated herein by reference in the entirety.

### TECHNICAL FIELD

The present invention generally relates to overlay metrology and, more particularly, to a system and method for overlay metrology allowing for compact pitch design of overlay targets.

### BACKGROUND

Demands to decrease feature size and increase feature density results in increased demand for accurate and efficient overlay metrology. Overlay metrology refers to measurements of the relative alignment of layers on a sample such as, but not limited to, semiconductor devices.

Overlay targets are typically formed on the surface of a wafer sample and may include cells with grating structures having various pitches in overlapping layers. A wafer sample is typically mounted on a translation stage and translated such that the overlay targets are sequentially moved into a measurement field of view. In typical metrology systems employing a move and measure (MAM) approach, the sample is static during each measurement. However, the time required for the translation stage to settle prior to a measurement may negatively impact the throughput.

Further, various sources may introduce errors into the overlay metrology data. Further, footprint space on a wafer is valuable.

Therefore, it is desirable to provide systems and methods for curing the above deficiencies.

### SUMMARY

An overlay metrology system is disclosed in accordance with one or more illustrative embodiments of the present disclosure. In one illustrative embodiment, the overlay metrology system may include a controller comprising one or more processors configured to execute program instructions causing the one or more processors to execute a metrology recipe. In another illustrative embodiment, the metrology recipe may include receiving detection signals from one or more detectors from an overlay target of a sample (e.g., wafer) and determining one or more overlay measurements of the overlay target based on the detection signals. In another illustrative embodiment, the overlay target may include a multi-layer structure on two or more layers of a cell of the sample. In another illustrative embodiment, the multi-layer structure may include structures in each layer having one or more pitches in one or more directions of periodicity. In another illustrative embodiment, the multi-layer structure may include structures with a first pitch in a first direction, a second pitch in a second direction, a third pitch in the first direction, and a fourth pitch in the second direction. In another illustrative embodiment, at least one of the first pitch or the third pitch may be different than at least one of the second pitch or the fourth pitch.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1A is a conceptual view of an overlay metrology system, in accordance with one or more embodiments of the present disclosure.

FIG. 1B is a schematic view of the optical sub-system, in accordance with one or more embodiments of the present disclosure.

FIG. 2A is a conceptual view of an illumination pupil plane distribution of a circular illumination beam, in accordance with one or more embodiments of the present disclosure.

FIG. 2B is a conceptual view of a collection pupil plane distribution of diffraction orders of the circular illumination beam of FIG. 2A, in accordance with one or more embodiments of the present disclosure.

FIG. 3 is a top view of an overlay target formed as an overlapping structure including two structures in two grid-like arrays, in accordance with one or more embodiments of the present disclosure.

FIG. 4 is a top view of an overlay target formed as an overlapping structure including a structure in a grid-like array and two gratings, in accordance with one or more embodiments of the present disclosure.

FIG. 5 is a top view of an overlay target which is narrow along a scan direction for reduced footprint, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Overlay metrology may be performed using a variety of overlay metrology techniques. For example, techniques include static move-and-measure modes where the sample is static during measurement and scanning modes where an illumination beam is scanned across the sample during measurement. In static scatterometry overlay (SCOL), the use of a charge-coupled device (CCD) camera requires time to read and transfer the data to a buffer for storage and two separate measurements per direction may be required. Thus, measuring a target is relatively time consuming. Scanning-based scatterometry measurement techniques, on the other hand, may be less time consuming and may include fast detectors to capture time-varying interference signals generated as the sample is scanned. The detectors may be placed in the pupil plane at locations of overlap between selected diffraction orders to capture time-varying interference signals as the sample is scanned. Various scanning scatterometry overlay metrology techniques are described in U.S. Patent Publication No. 2022/0034652 filed on Feb. 17, 2021; U.S. patent application Ser. No. 17/119,536 filed on Dec. 11, 2020; U.S. patent application Ser. No. 17/708,958 filed on Mar. 30, 2022; U.S. patent application Ser. No. 17/709,104 filed on Mar. 30, 2022; and U.S. patent application Ser. No. 17/709,200 filed on Mar. 30, 2022; which are all incorporated herein by reference in their entireties. Note that such scanning examples are nonlimiting and embodiments herein may include one or more detectors in a field plane and may include various types of detectors such as one or more diode array sensors.

Embodiments herein may work well with scanning SCOL techniques, but are not necessarily limited to such techniques.

In some scanning methods, the scanning targets may include separate targets and/or separate cells for each direction (e.g., an X-direction and a Y-direction) that are measured separately. For example, two cells may be placed sequentially as shown in FIG. 6B of U.S. patent application Ser. No. 18/099,798, filed Jan. 20, 2023, the entirety of which is hereby incorporated by reference. While U.S. patent application Ser. No. 18/099,798 discloses reducing overlay error by reversing the order of pitches of multi-layer gratings in two or more cells, the present disclosure may allow for more compact (e.g., single cell) overlay targets.

Embodiments of the present disclosure are directed to an overlay metrology system configured to determine an overlay measurement of an overlay target having a single cell with different pitches along each of two orthogonal directions (e.g., an X-direction and a Y-direction). Having different pitches in each direction allows for avoiding cross-talk between overlay measurements in each direction so that data capture of corresponding time-varying X and Y signals can be clearly distinguished.

Avoiding cross-talk may mean that X and Y pitch signals can be clearly distinguished from each other. For example, without the present disclosure, single-cell overlay targets measured diagonally may cause cross-talk to occur if structures are not spaced differently in the X-direction compared to a spacing in the Y-direction. However, embodiments herein may allow for reduced cross-talk compared to such a scenario by using at least one different spacing (i.e., pitch) of structures in each direction. For instance, a grid of structures (e.g., non-connected rectangles and/or squares in rows and columns) in a single layer with a spacing (i.e., first pitch) between the rows and a second spacing (i.e., second pitch) between the columns may be used. Two more pitches may be embodied in another layer with a grid of structures or two more layers with a grating in each layer, which may provide at least four pitches. Further, at least one pitch in each direction is different from each other. For example, the first pitch in an X-direction may be different from one of the pitches in the Y-direction, such as the second pitch of a grating pitch in the Y-direction.

It is contemplated herein that structures featuring different pitches in each direction could potentially offer distinct advantages. Notably, these structures can effectively mitigate cross-talk, specifically within the measurements. For example, scanning measurements of an overlay target may be performed in the X-direction and also in the Y-direction—also a scan may be performed diagonally in both the X-direction and Y-direction. The measurements in each scenario may benefit from reduced cross-talk by being based on a target with different pitches in each direction. With wafer footprints becoming increasingly dense and valuable, minimizing the footprint size of an overlay target could free up valuable space. This could increase wafer chip throughput.

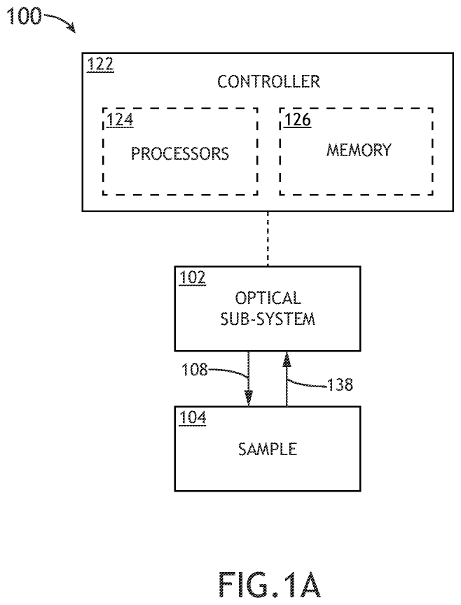

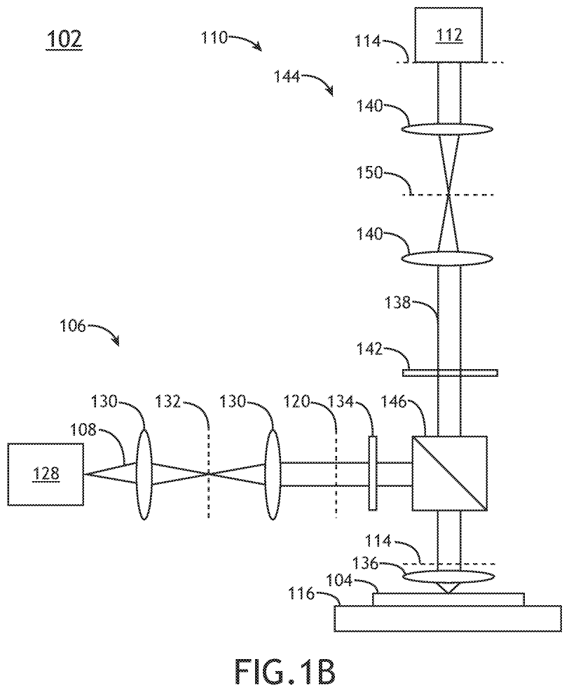

FIG. 1A illustrates a conceptual view of an overlay metrology system 100, in accordance with one or more embodiments of the present disclosure.

In embodiments, the overlay metrology system 100 includes an optical sub-system 102 configured to acquire one or more images from a sample 104 (e.g., wafer) for use in determining overlay measurements.

In embodiments, overlay metrology system 100 includes a controller 122. The controller 122 may include one or more processors 124 and memory 126. For example, the controller 122 may be configured to determine an overlay measurement based on signals received from a detector of the optical sub-system 102

FIG. 1B illustrates a simplified schematic view of the optical sub-system 102, in accordance with one or more embodiments of the present disclosure.

In embodiments, optical sub-system 102 includes an illumination sub-system 106 and a collection sub-system 110.

The illumination sub-system 106 is configured to generate illumination in the form of one or more illumination beams 108 to illuminate the sample 104. The collection sub-system 110 is configured to collect light from the illuminated sample 104 (e.g., according to a metrology recipe). Further, the one or more illumination beams 108 may be spatially limited such that they may illuminate selected portions of the sample 104. For instance, each of the one or more illumination beams 108 may be spatially limited to illuminate a particular cell of an overlay target.

In embodiments, an illumination beams 108 is split (e.g., via an additional beamsplitter) prior to the sample 104 to generate an external beam (e.g., auxiliary beam) for purposes of phase reference (e.g., holography). For example, U.S. patent application Ser. No. 18/110,746, filed Feb. 16, 2023, which is hereby incorporated by reference in its entirety, discloses an auxiliary beam that is split off and combined with diffraction orders from a sample. For instance, an external beam (e.g., a portion of an illumination beam 108) may be overlapped with selected diffraction orders from the sample 104 to generate time-varying interference signals suitable for overlay measurements as disclosed herein. This configuration may reduce constraints on a design of an overlay target and may enable features with relatively small pitches that provide little or no overlap between diffraction lobes in a pupil plane.

For example, overlay metrology system 100 may be configured to image certain types of samples, according to a metrology recipe. For instance, the overlay metrology system 100 may be designed (configured) and/or programmed (e.g., programmed via program instructions) to calculate overlay measurements of certain types of features of a sample 104 (e.g., grating-over-grating target) according to a metrology recipe.

In embodiments, the optical sub-system 102 may include a translation stage 116 to scan the sample 104 through a measurement field of view of the optical sub-system 102 during an overlay measurement.

As noted previously herein, the overlay metrology system 100 may include one or more detectors 112 for scanning overlay metrology. In embodiments, the one or more detectors 112 may include any type of optical detector known in the art suitable for capturing interference signals generated as the sample 104 is translated by a translation stage 116 and/or as one or more illumination beams 108 are scanned by the optical sub-system 102. For example, the one or more detectors 112 may be diode array sensors and/or charge-coupled device (CCD) sensors.

In embodiments, the one or more detectors 112 are located in a collection pupil plane 114 such that diffraction orders emanating from the sample 104 may be measured.

For example, performing scanning-based overlay metrology may include receiving detection signals from one or more detectors 112 while the sample 104 is in motion such that the detection signals are time-varying interference signals.

In embodiments, the optical sub-system 102 may perform scatterometry overlay measurements on portions of the sample 104 having overlay targets such as, but not limited to, grating-over-grating targets.

It is recognized herein that the distribution of diffraction orders of an illumination beam 108 created by periodic structures (e.g., grating-over-grating structures) may be influenced by a variety of parameters such as, but not limited to, a wavelength of the illumination beam 108, an incidence angle of the illumination beam 108 in both altitude and azimuth directions, a period (i.e., pitch) of the periodic structures, or a numerical aperture (NA) of a collection lens. For example, the illumination sub-system 106, the collection sub-system 110, and/or an overlay target may be configured to provide an overlapping distribution of zero-order diffraction and first-order diffraction in the collection pupil plane 114 of the collection sub-system 110. The illumination sub-system 106 and/or the collection sub-system 110 may be configured to determine or facilitate measurements on grating-over-grating structures having a selected range of periodicities that provide the overlapping distribution. As another example, the illumination sub-system, the collection sub-system 110, and/or an overlay target may be configured to overlap first-order diffraction from the overlay target with a portion of an illumination beam 108 (e.g., an external beam, an auxiliary beam, or the like). Further, various components of the illumination sub-system 106 and/or the collection sub-system 110 (e.g., stops, pupils, or the like) may be adjustable to provide an overlapping distribution for a given structure suitable for generating time-varying signals from which an overlay measurement may be determined.

The collection sub-system 110 may be configured to collect at least one of 0-order diffraction (e.g., specular reflection) and +/−1 diffraction orders from the sample 104 associated with diffraction of the illumination beam 108.

In embodiments, the optical sub-system 102 includes an objective lens 136 to focus the illumination beam 108 onto the sample 104 (e.g., onto an overlay target with structures located on two or more layers of the sample 104). The objective lens 136 may be configured to collect measurement light emanating from a sample 104 in response to the illumination beam 108 as the sample 104 is scanned along a scan direction.

The optical sub-system 102 may implement a variety of illumination beam distributions. For example, the illumination beam 108 may be circular, annular, and/or the like.

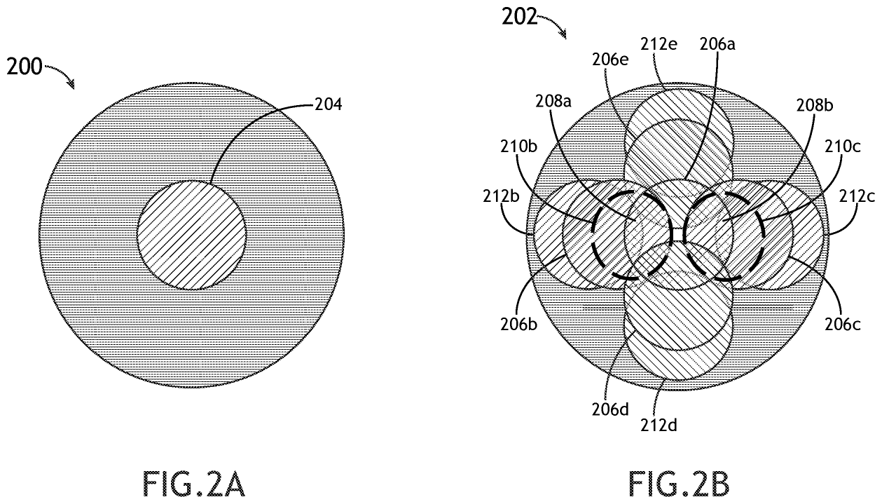

FIG. 2A illustrates a conceptual view of an illumination pupil plane distribution 200 of a circular illumination beam 204, in accordance with one or more embodiments of the present disclosure.

FIG. 2B illustrates a conceptual view of a collection pupil plane distribution 202 of diffraction orders of the circular illumination beam 204 of FIG. 2A, in accordance with one or more embodiments of the present disclosure. For example, a circular illumination beam 204 may—after emanating from the sample 104—become a measurement beam of collectable light 138 and form circular diffraction orders in a collection pupil plane 114. For a target with pitches and edges in both the X-direction, and the Y-direction, diffraction orders are generated in the horizontal and vertical direction of the pupil plane as shown by the five circles in the horizontal and five circles in the vertical of FIG. 2B. Circular diffraction orders in the X-direction may include zero order (0) circular diffraction order 206a, first order (+1) X circular diffraction order 206c, first order (−1) X circular diffraction order 206b, second order (+1) X circular diffraction order 212c, and second order (−1) X circular diffraction order 212b. In the Y-direction, the circular diffraction orders may include the zero order (0) circular diffraction order 206a, first order (+1) Y circular diffraction order 206e, first order (−1) Y circular diffraction order 206d, second order (+1) Y circular diffraction order 212e, and second order (−1) Y circular diffraction order 212d. The one or more detectors 112 may be placed to capture the overlapping regions 208a, 208b of such diffraction orders. For example, detectors 112 (e.g., diode array sensors) may be placed in the pupil plane 114 such that the one or more detectors 112 capture light from detected regions 210c, 210b corresponding to diffraction orders in the X-direction. Note that for clarity and simplicity only the X-direction detected regions 210c, 210b are labeled but corresponding overlapping regions in the Y-direction may be captured by similar detected regions (not shown) in the Y-direction. Note that the detected regions 210c, 210b may be any size, such as smaller, equal, or larger than the overlapping regions 208a, 208b.

When scanning diagonally, signals may include diffraction orders emanating from structures with pitches in both X and Y directions, and thus overlay may be determined in both of the X and Y directions using a single diagonal scan. FIG. 2B illustrates both X and Y direction diffraction orders from pitches in X and Y directions. For example, the detection signals (of a diagonal scan) may comprise first detection signals corresponding to diffraction orders in the first direction (e.g., X-direction), and second detection signals corresponding to diffraction orders in the second direction (e.g., Y-direction). In embodiments, a determination of overlay measurements may include determining a first direction overlay measurement based on the first detection signals; and determining a second direction overlay measurement based on the second detection signals. For instance, a first direction overlay measurement may be indicative of overlay between a first structures 310 and second structures 308 in the X-direction, which may be used to adjust fabrication processes to reduce unwanted overlay.

For example, the first detection signals may be based on (e.g., correspond to) overlapping of diffraction orders 206a, 210b, 212b, 210c, and/or 212c. For instance, first detection signals may be received from X-direction detected regions 210c, 210b using a detector 112 (e.g., photodiode detector) placed in each of the X-direction detected regions 210c, 210b. The second detection signals may be based on overlapping of diffraction orders 206a, 210d, 212d, 210e, and/or 212e.

Further, in this way, the determination of overlay measurements may include: determining a first direction overlay measurement (e.g., X-direction overlay in the X-direction) based on the first detection signals; and determining a second direction overlay measurement (e.g., Y-direction overlay) based on the second detection signals. Such determinations may be based on differences between various overlapping regions, such as a difference in time-varying light intensity of overlapping region 208a and overlapping region 208b to determine an X-direction overlay. In this way, a single diagonal scan may be used to simultaneously determine overlay in two directions.

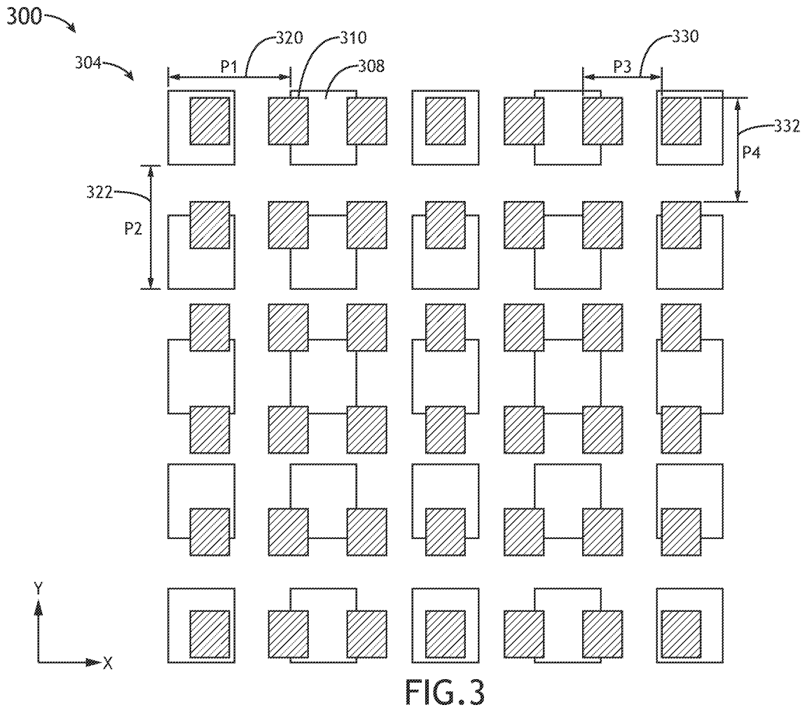

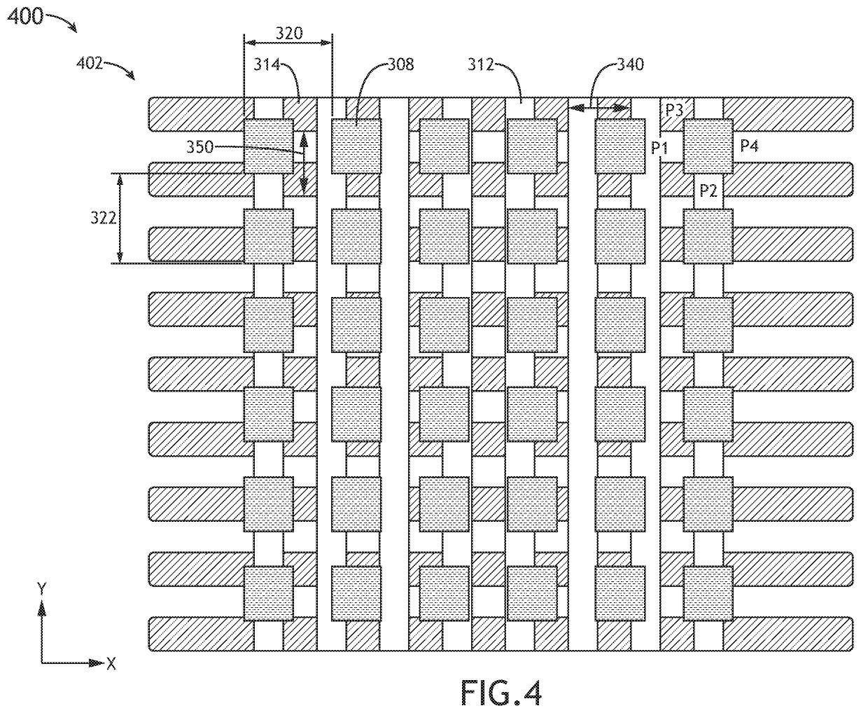

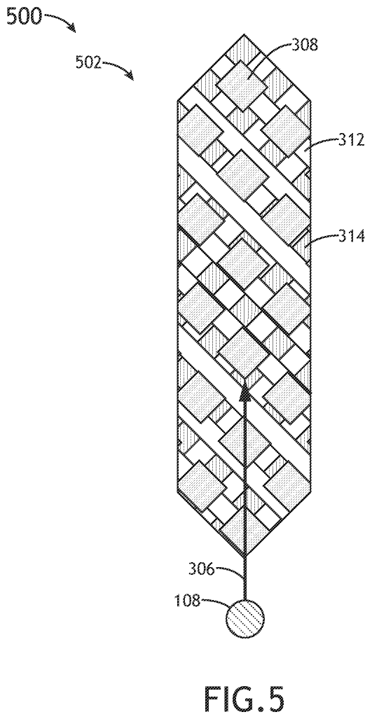

FIGS. 3-5 are examples of overlay targets where a different pitch in the X-direction compared to a pitch in the Y-direction allows simultaneous data capture of corresponding time-varying signals in a way that avoids cross-talk so X and Y signals can be clearly distinguished. FIG. 3 is a Moiré target with grid structures on the two layers. FIG. 4 is a three-layer overlay target with a grid structure on one layer and line/space features on two other layers. This allows measurements between the grid layer and each of the line/space layers for each respective direction. Both FIG. 3 and FIG. 4 allow scanning diagonally between X and Y directions to determine X and Y overlay measurements simultaneously—or for scanning X and Y directions separately. FIG. 5 illustrates how the overlay target of FIG. 4 may be made smaller and narrower when scanning diagonally.

FIG. 3 illustrates a top view 300 of an overlay target 304 formed as an overlapping structure including two sets of structures 308, 310 in two grid-like arrays, in accordance with one or more embodiments of the present disclosure.

In embodiments, the overlay target 304 comprises a multi-layer structure on two or more layers of a cell of the sample 104. For example, the multi-layer structure may comprise structures in each layer having one or more pitches in one or more directions of periodicity in a single cell. In embodiments, overlay targets herein may have (at least) four pitches, with at least one pitch in a first direction different from another pitch in a second direction. For example, the overlay targets may include a first and third pitch in the first direction, and a second and fourth pitch in the second direction. For instance, at least one of the first and third pitches may be different from at least one of the second and fourth pitches. In this way, a different pitch in each direction is achieved, reducing crosstalk. Such pitches can be in the same layer (e.g., grid patterns with two pitches, one in each direction) and/or different layers (e.g., more conventional diffraction gratings with a single pitch in a single direction).

In embodiments, the overlay target 304 includes a multi-layer structure 304 formed as an overlapping structure with different pitches on two or more layers of a sample 104. For example, the two or more layers of the sample 104 may include at least a first layer and a second layer (as shown). For instance, the multi-layer structure 304 may include at least two different first-direction (e.g., X-direction) pitches 320, 330 and at least two different second-direction (e.g., Y-direction orthogonal to X-direction) pitches 322, 332. The multi-layer structure may include at least a first-layer array of first structures 310 with periodicity in a first direction and second direction. Such periodicity may be the first pitch 320 and the second pitch 322 such that the first structures 310 may include a first pitch 320 in the first direction and a second pitch 322 in the second direction.

To achieve two pitches in each direction, various additional layers with various structures may be used besides a layer with grid structures. For example, a second layer of structures 308 in a second grid may be used as shown in FIG. 3. Using a (first) grid and a second grid, one on each layer, allows for having four total pitches on only two layers in a single cell. By way of another example, two more layers (i.e., a second layer and a third layer) with gratings on each layer may be used as shown by gratings 312, 314 in FIGS. 4 and 5. In this way, only three layers in a single cell are needed to achieve four pitches (i.e., a grid with two pitches in one layer, and two more layers with a grating in each of the two more layers).

In embodiments, the multi-layer structure 304 may include a second-layer array of second structures 308 with periodicity in the first direction and the second direction. The second structures 308 may include a third pitch 340 in the first direction and a fourth pitch 350 in the second direction. The first pitch 320 and the third pitch 340, which are in the first direction, may be different, and the second pitch 322 and the fourth pitch 350, which are in the second direction, may be different.

FIG. 4 illustrates a top view 400 formed as an overlapping structure 402 including a structure 310 in a grid-like array and two gratings 312, 314, in accordance with one or more embodiments of the present disclosure.

In embodiments, the multi-layer structure 304 further includes a second-layer grating 312 on a second layer with a third pitch 340 in the first direction.

In embodiments, the multi-layer structure 304 further includes a third-layer grating 314 on a third layer with a fourth pitch 350 in the second direction. The fourth pitch 350 may be different than the first pitch 320 and/or the third pitch 340. In this way, a different pitch in each direction is achieved. Alternatively, and/or in addition, the second pitch 322 may be different than the first pitch 320 and/or the third pitch 340. In this way, a different pitch in each direction is achieved.

FIG. 5 illustrates a top view 500 of an overlay target 502 which is narrow along a scan direction 306 for reduced footprint, in accordance with one or more embodiments of the present disclosure. The illumination beam 108 is scanned along a scan direction 306. Scanning the overlay target 304 by a length equal to a pitch of a grating-over-grating structure may result in a phase shift of 2π in each of the +/−1 diffraction orders (in opposite directions) and the intensity captured by each of the one or more detectors 112 may oscillate through an interference fringe.

In embodiments, the multi-layer structure is configured to be scanned separately along both the first and second direction (e.g., along the periodicity of the pitches) and/or along a third direction 306 (i.e., diagonally). In embodiments, the third direction 306 is different from the first direction and the second direction.

In embodiments, such scanning may be used with a photodiode-based scanning scatterometry overlay (e.g., SCOLAR) system and/or method. For example, the illumination beam 108 may scan each target in the X-direction and then the Y-direction, or vice versa. In another example, the illumination beam 108 may be scanned diagonally along a narrow, diagonal-periodicity target such as the overlay target 502 shown in FIG. 5. For example, the third direction 306 may be within 10 degrees of 45 degrees from the first direction and the second direction of periodicity.

In embodiments, a relatively narrow overlay target 502 is used, as shown in FIG. 5. For example, the multi-layer structure 502 may have a scan length (i.e., overall length of the overlay target 502) along the third direction 306 that is greater than a width (i.e., overall width) of the multi-layer structure 502, where the width is measured orthogonal (i.e., 90 degrees) to the third direction 306. This may define a narrow overlay target 502 including edges that are parallel to the scanning direction and configured to be scanned at a third direction (e.g., diagonally) different than the first and second directions. For example, rather than performing a diagonal scan from corner to corner of a diamond shape (e.g., rotated square overlay target)—where the distal corners on each side jut outwards to the left and right, the design may be cropped such that the outer corner edges are, in a sense, trimmed inwards to be narrower. Using a narrower overlay target 502 saves space on the sample 104 for other features.

As shown, the illumination beam 108 may occupy a spot size that is smaller than the overlay target 304 itself. It is to be understood, however, that the overlay targets in FIGS. 3 through 5 and the associated descriptions are provided solely for illustrative purposes and should not be interpreted as limiting.

Referring again to FIGS. 1A-1B, additional components of the optical sub-system 102 are described, in accordance with one or more embodiments of the present disclosure. For example, controller 122 and processors 124 and various optical components are described below in detail for overlay metrology.

In embodiments, the controller 122 determines an overlay measurement between layers of an overlay target 304 (e.g., the first layer and the second layer) along the measurement direction based on the comparison of the detection signals. For example, the controller 122 may compare the magnitudes and/or phases of the detection signals to determine an overlay measurement. For instance, U.S. Pat. No. 10,824,079 issued on Nov. 3, 2020 incorporated herein by reference in its entirety describes diffracted orders in a collection pupil and further provides specific relationships between overlay and measured intensity in the pupil plane. It is contemplated herein that the systems and methods disclosed herein may extend the teachings of U.S. Pat. No. 10,824,079 to detection signals captured by one or more detectors placed in overlap regions between 0 and +/−1 diffraction orders. In particular, it is contemplated herein that overlay on a sample may be proportional to a relative phase shift between two detection signals. In another instance, the relative intensities of the diffraction orders in the pupil plane may be extracted from the detection signals. In this way, any overlay algorithm based on relative intensity differences of diffraction orders known in the art may be applied to determine an overlay measurement.

In embodiments, the overlay metrology system 100 includes a controller 122 communicatively coupled to the optical sub-system 102. The controller 122 may include one or more processors 124 and a memory device 126, or memory. For example, the one or more processors 124 may be configured to execute a set of program instructions maintained in the memory device 126.

The one or more processors 124 of the controller 122 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 124 may include any device configured to execute algorithms and/or instructions (e.g., program instructions stored in memory). In one embodiment, the one or more processors 124 may be embodied as a desktop computer, mainframe computer system, workstation, image computer, parallel processor, networked computer, or any other computer system configured to execute a program configured to operate or operate in conjunction with the overlay metrology system 100, as described throughout the present disclosure. Moreover, different subsystems of the overlay metrology system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 122 may include one or more controllers housed in a common housing or within multiple housings. In this way, any controller or combination of controllers may be separately packaged as a module suitable for integration into system 100. Further, the controller 122 may analyze or otherwise process data received from the one or more detectors 112 and feed the data to additional components within the overlay metrology system 100 or external to the overlay metrology system 100.

Further, the memory device 126 may include any storage medium known in the art suitable for storing program instructions executable by the associated one or more processors 124. For example, the memory device 126 may include a non-transitory memory medium. As an additional example, the memory device 126 may include, but is not limited to, a read-only memory, a random-access memory, a magnetic or optical memory device (e.g., disk), a magnetic tape, a solid-state drive and the like. It is further noted that memory device 126 may be housed in a common controller housing with the one or more processors 124.

In this regard, the controller 122 may execute any of various processing steps associated with overlay metrology. For example, the controller 122 may be configured to determine control signals to direct or otherwise control the optical sub-system 102, or any components thereof. For instance, the controller 122 may be configured to direct the translation stage 116 to translate the sample 104 along one or more measurement paths, or swaths, to scan one or more overlay targets through a measurement field of view of the optical sub-system 102. By way of another example, the controller 122 may be configured to receive signals corresponding to the detection signals from the one or more detectors 112. By way of another example, the controller 122 may determine correctables for one or more additional fabrication tools as feedback and/or feed-forward control of the one or more additional fabrication tools based on overlay measurements from the optical sub-system 102.

In embodiments, the controller 122 captures the detection signals detected by the one or more detectors 112. The controller 122 may generally capture data such as, but not limited to, the magnitudes or the phases of the detection signals using any technique known in the art such as, but not limited to, one or more phase-locked loops. Further, the controller 122 may capture the detection signals (e.g., detection signals), or any data associated with the detection signals, using any combination of hardware (e.g., circuitry) or software techniques.

Referring again to FIG. 1B, various components of the optical sub-system 102 are described in greater detail in accordance with one or more embodiments of the present disclosure.

In embodiments, the illumination sub-system 106 includes an illumination source 128 configured to generate at least one illumination beam 108. The illumination from the illumination source 128 may include one or more selected wavelengths of light including, but not limited to, ultraviolet (UV) radiation, visible radiation, or infrared (IR) radiation.

In embodiments, the illumination sub-system 106 includes one or more optical components suitable for modifying and/or conditioning the illumination beam 108 as well as directing the illumination beam 108 to the sample 104. For example, the illumination sub-system 106 may include one or more illumination lenses 130 (e.g., to collimate the illumination beam 108, to relay an illumination pupil plane 120 and/or an illumination field plane 132, or the like). In another embodiment, the illumination sub-system 106 includes one or more illumination control optics 134 to shape or otherwise control the illumination beam 108. For example, the illumination control optics 134 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

The collection sub-system 110 may include one or more optical elements suitable for modifying and/or conditioning the collected light 138 from the sample 104. In one embodiment, the collection sub-system 110 includes one or more collection lenses 140 (e.g., to collimate the illumination beam 108, to relay pupil and/or field planes, or the like), which may include, but are not required to include, the objective lens 136. In another embodiment, the collection sub-system 110 includes one or more collection control optics 142 to shape or otherwise control the collected light 138. For example, the collection control optics 142 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like). In another example, the collection sub-system 110 may include one or more collection field planes 150.

In embodiments, the collection sub-system 110 includes two or more collection channels 144, each with a separate detector 112 (or multiple detectors 112). For example, the optical sub-system 102 may include one or more beamsplitters 146 arranged to split the collected light 138 into the collection channels 144. Further, the beamsplitters 146 may be polarizing beamsplitters, non-polarizing beamsplitters, or a combination thereof.

Referring again to FIG. 1A, it is noted herein that the one or more components of overlay metrology system 100 may be communicatively coupled to the various other components of system 100 in any manner known in the art. For example, the one or more processors 124 may be communicatively coupled to each other and other components via a wireline (e.g., copper wire, fiber optic cable, and the like) or wireless connection (e.g., RF coupling, IR coupling, WiMax, Bluetooth, 3G, 4G, 4G LTE, 5G, and the like). By way of another example, the controller 122 may be communicatively coupled to one or more components of optical sub-system 102 via any wireline or wireless connection known in the art.

In one embodiment, the one or more processors 124 may include any one or more processing elements known in the art. In this sense, the one or more processors 124 may include any microprocessor-type device configured to execute software algorithms and/or instructions. In one embodiment, the one or more processors 124 may consist of a desktop computer, mainframe computer system, workstation, image computer, parallel processor, or other computer system (e.g., networked computer) configured to execute a program configured to operate the overlay metrology system 100, as described throughout the present disclosure. It should be recognized that the steps described throughout the present disclosure may be carried out by a single computer system or, alternatively, multiple computer systems. Furthermore, it should be recognized that the steps described throughout the present disclosure may be carried out on any one or more of the one or more processors 124. In general, the term “processor” may be broadly defined to encompass any device having one or more processing elements, which execute program instructions from memory 126. Moreover, different subsystems of the overlay metrology system 100 may include processor or logic elements suitable for carrying out at least a portion of the steps described throughout the present disclosure. Therefore, the above description should not be interpreted as a limitation on the present disclosure but merely an illustration.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be affected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

We claim:

1. An overlay metrology system comprising:
an illumination sub-system comprising:
an illumination source configured to generate an illumination beam;
a collection sub-system comprising:
one or more detectors; and
an objective lens configured to collect measurement light emanating from a sample in response to the illumination beam as the sample is scanned, wherein the sample comprises an overlay target according to a metrology recipe; and
a controller communicatively coupled to the collection sub-system, the controller comprising one or more processors configured to execute program instructions causing the one or more processors to execute the metrology recipe by:
receiving detection signals from the one or more detectors from the overlay target;
determining one or more overlay measurements of the overlay target based on the detection signals; and
wherein the overlay target, according to the metrology recipe, comprises a multi-layer structure on two or more layers of a cell of the sample, the multi-layer structure comprising structures in each layer having one or more pitches in one or more directions of periodicity,
wherein the multi-layer structure comprises the structures with a first pitch in a first direction, a second pitch in a second direction, a third pitch in the first direction, and a fourth pitch in the second direction, wherein at least one of the first pitch or the third pitch is different than at least one of the second pitch or the fourth pitch.

2. The overlay metrology system of claim 1, wherein the scanning of the sample comprises one or more scans in one or more scan directions, wherein the one or more scan directions comprise the first direction and the second direction.

3. The overlay metrology system of claim 1, wherein the scanning of the sample comprises one or more scans in one or more scan directions, wherein the one or more scan directions comprise a third direction different than both the first direction and the second direction.

4. The overlay metrology system of claim 3, wherein the detection signals comprise first detection signals corresponding to diffraction orders in the first direction, and second detection signals corresponding to diffraction orders in the second direction.

5. The overlay metrology system of claim 4, wherein the determination of the one or more overlay measurements comprises:
determining a first direction overlay measurement based on the first detection signals; and
determining a second direction overlay measurement based on the second detection signals.

6. The overlay metrology system of claim 1, wherein the one or more detectors comprise at least one detector located in a pupil plane.

7. The overlay metrology system of claim 1, wherein the one or more detectors comprise at least one diode array sensor.

8. The overlay metrology system of claim 1, wherein an illumination pupil plane distribution of the illumination beam is circular.

9. The overlay metrology system of claim 1, wherein an illumination pupil plane distribution of the illumination beam is annular.

10. The overlay metrology system of claim 1, wherein the detection signals include time-varying interference signals associated with overlap between first-order diffraction and zero order diffraction from the multi-layer structure.

11. The overlay metrology system of claim 1, the illumination sub-system further comprising a beamsplitter configured to generate an external beam as a portion of the illumination beam, wherein the detection signals include time-varying interference signals associated with overlap between first-order diffraction from the multi-layer structure and the external beam.

12. An overlay metrology system comprising:
a controller comprising one or more processors configured to execute program instructions causing the one or more processors to execute a metrology recipe by:
receiving detection signals from one or more detectors from an overlay target of a sample;
determining one or more overlay measurements of the overlay target based on the detection signals; and
wherein the overlay target, according to the metrology recipe, comprises a multi-layer structure on two or more layers of a cell of the sample, the multi-layer structure comprising structures in each layer having one or more pitches in one or more directions of periodicity,
wherein the multi-layer structure comprises the structures with a first pitch in a first direction, a second pitch in a second direction, a third pitch in the first direction, and a fourth pitch in the second direction, wherein at least one of the first pitch or the third pitch is different than at least one of the second pitch or the fourth pitch.

13. The overlay metrology system of claim 12, wherein the controller is further configured to execute the metrology recipe by scanning the sample along one or more scan directions, wherein the one or more scan directions comprise the first direction and the second direction.

14. The overlay metrology system of claim 12, wherein the controller is further configured to execute the metrology recipe by scanning of the sample along one or more scan directions, wherein the one or more scan directions comprise a third direction different than both the first direction and the second direction.

15. The overlay metrology system of claim 12, wherein the one or more detectors comprise at least one detector located in a pupil plane.

16. The overlay metrology system of claim 12, wherein the one or more detectors comprise at least one diode array sensor.

17. An overlay metrology target comprising:
a multi-layer structure on two or more layers of a cell of a sample, the multi-layer structure comprising structures in each layer having one or more pitches in one or more directions of periodicity,
wherein the multi-layer structure comprises the structures with a first pitch in a first direction, a second pitch in a second direction, a third pitch in the first direction, and a fourth pitch in the second direction, wherein at least one of the first pitch or the third pitch is different than at least one of the second pitch or the fourth pitch.

18. The overlay metrology target of claim 17, wherein the multi-layer structure comprises:
a first-layer array on a first layer with the first pitch in the first direction and the second pitch in the second direction.

19. The overlay metrology target of claim 17, wherein the multi-layer structure comprises:
a second-layer grating on a second layer with the third pitch in the first direction.

20. The overlay metrology target of claim 19, wherein the multi-layer structure comprises:
a third-layer grating on a third layer with the fourth pitch in the second direction.

21. The overlay metrology target of claim 20, wherein the multi-layer structure is configured to be scanned along a third direction, wherein the third direction is different from the first direction and the second direction.

22. The overlay metrology target of claim 21, wherein the multi-layer structure has a scan length along the third direction that is greater than a width of the multi-layer structure, wherein the width is measured orthogonal to the third direction.

23. The overlay metrology target of claim 17, wherein the multi-layer structure is configured to be scanned along a third direction, wherein the third direction is different from the first direction and the second direction, wherein the third direction is within 10 degrees of 45 degrees from the first direction and the second direction.

24. The overlay metrology target of claim 17, wherein the multi-layer structure further comprises:
a second-layer array on a second layer with the third pitch in the first direction and the fourth pitch in the second direction.
